(19) United States
(12) Patent Application Publication
(10) Pub. No.: US 2018/0106876 A1
(43) Pub. Date: Apr. 19, 2018

(54) MAGNETIC RESONANCE FINGERPRINTING WITH REDUCED SENSITIVITY TO INHOMOGENEITIES IN THE MAIN MAGNETIC FIELD

(71) Applicant: KONINKLIJKE PHILIPS N.V., EINDHOVEN (NL)

(72) Inventors: TIM NIELSEN, HAMBURG (DE); PETER BOERNERT, HAMBURG (DE); KAY NEHRKE, AMMERSBEK (DE); THOMAS ERIK AMTHOR, HAMBURG (DE); MARIYA IVANOVA DONEVA, HAMBURG (DE)

(21) Appl. No.: 15/565,194

(22) PCT Filed: Apr. 13, 2016
(86) PCT No.: PCT/EP2016/058048

§ 371 Date: Oct. 9, 2017

Related U.S. Application Data
(60) Provisional application No. 62/206,327, filed on Aug. 18, 2015.

(30) Foreign Application Priority Data
Apr. 14, 2015 (EP) 15163505.9

(51) Int. Cl. G01R 33/44; G01R 33/50; G01R 33/561; G01R 33/54

(52) U.S. Cl. CPC G01R 33/445; G01R 33/50; G01R 33/5612; G01R 33/543; G01R 33/546; G01R 33/5617

(57) ABSTRACT

The invention provides for a magnetic resonance system (100) comprising a magnet (104) for generating a main magnetic field within the measurement zone and a magnetic field gradient system (110, 112) for generating a gradient magnetic field within the measurement zone in at least one direction by supplying current to a set of magnetic gradient coils (112) for each of the at least one direction. Instructions cause a a processor (130) controlling the magnetic resonance system, wherein execution of the machine executable instructions causes the processor to acquire (200) the magnetic resonance data by controlling the magnetic resonance system with pulse sequence commands. The pulse sequence commands (140) cause the magnetic resonance system to acquire the magnetic resonance data according to a magnetic resonance fingerprinting technique. The pulse sequence commands specify a train (500) of pulse sequence repetitions (502, 504), each with a fixed repetition time (302). Each repetition comprises either a radio frequency pulse (310) chosen from a distribution of radio frequency pulses or a sampling event (404) occurring at a fixed delay (316) from the start of the pulse sequence repetition. The pulse sequence commands specify the application of gradient (308) magnetic fields in the at least one direction by controlling the supplied current to the set of gradient coils. Each of the set of magnetic gradient coils the integral of current supplied is a constant for each fixed repetition time. The instructions further cause the processor to calculate (202) the abundance of each of a set of predetermined substances by comparing the magnetic resonance data with a magnetic resonance fingerprinting dictionary (144).

### TECHNICAL FIELD OF THE INVENTION

The invention relates to magnetic resonance imaging, in particular techniques for performing magnetic resonance fingerprinting.

### BACKGROUND OF THE INVENTION

Magnetic Resonance (MR) fingerprinting is a new technique where a number of RF pulses, distributed in time, are applied such that they cause signals from different materials or tissues to have a unique contribution to the measured MR signal. A limited dictionary of precalculated signal contributions from a set or fixed number of substances is compared to the measured MR signals and within a single voxel the composition can be determined. For example if it is known that a voxel only contains water, fat, and muscle tissue the contribution from these three materials need only be considered and only a few RF pulses are needed to accurately determine the composition of the voxel. If a larger dictionary with higher resolution is used, MR fingerprinting can be used to determine different tissue parameters of a voxel (such as T1, T2, . . . ) simultaneously and quantitatively.

The magnetic resonance fingerprinting technique was introduced in the journal article Ma et al., “Magnetic Resonance Fingerprinting,” Nature, Vol. 495, pp. 187 to 193, doi:10.1038/nature11971. The magnetic fingerprinting technique is also described in United States patent applications US 2013/0271132 A1 and US 2013/0265047 A1.

The conference proceeding Jiang et al., “MR Fingerprinting Using Spiral QUEST,” Proc. Intl. Soc. Mag. Reson. Med. 21 (2013), p. 0019, discloses Magnetic Resonance Fingerprinting (MRF) by using the QUick Echo Split imaging Technique (QUEST) as a building block for MRF sequences.

### SUMMARY OF THE INVENTION

The invention provides for a magnetic resonance imaging system, a computer program product and a method in the independent claims. Embodiments are given in the dependent claims.

The Nature article by Ma et al. introduces the basic idea of magnetic resonance fingerprinting and terminology which is used to describe this technique such as the dictionary, which is referred to herein as a “pre-calculated magnetic resonance fingerprinting dictionary,” a “magnetic resonance fingerprinting dictionary,” and a “dictionary.”

As will be appreciated by one skilled in the art, aspects of the present invention may be embodied as an apparatus, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer executable code embodied thereon.

Any combination of one or more computer readable medium(s) may be utilized. The computer readable medium may be a computer readable signal medium or a computer readable storage medium. A ‘computer-readable storage medium’ as used herein encompasses any tangible storage medium which may store instructions which are executable by a processor of a computing device. The computer-readable storage medium may be referred to as a computer-readable non-transitory storage medium. The computer-readable storage medium may also be referred to as a tangible computer readable medium. In some embodiments, a computer-readable storage medium may also be able to store data which is able to be accessed by the processor of the computing device. Examples of computer-readable storage media include, but are not limited to: a floppy disk, a magnetic hard disk drive, a solid state hard disk, flash memory, a USB thumb drive, Random Access Memory (RAM), Read Only Memory (ROM), an optical disk, a magneto-optical disk, and the register file of the processor. Examples of optical disks include Compact Disks (CD) and Digital Versatile Disks (DVD), for example CD-ROM, CD-RW, CD-R, DVD-ROM, DVD-RW, or DVD-R disks. The term computer readable-storage medium also refers to various types of recording media capable of being accessed by the computer device via a network or communication link. For example a data may be retrieved over a modem, over the internet, or over a local area network. Computer executable code embodied on a computer readable medium may be transmitted using any appropriate medium, including but not limited to wireless, wire line, optical fiber cable, RF, etc., or any suitable combination of the foregoing.

A computer readable signal medium may include a propagated data signal with computer executable code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

‘Computer memory’ or ‘memory’ is an example of a computer-readable storage medium. Computer memory is any memory which is directly accessible to a processor. ‘Computer storage’ or ‘storage’ is a further example of a computer-readable storage medium. Computer storage is any non-volatile computer-readable storage medium. In some embodiments computer storage may also be computer memory or vice versa.

A ‘processor’ as used herein encompasses an electronic component which is able to execute a program or machine executable instruction or computer executable code. References to the computing device comprising “a processor” should be interpreted as possibly containing more than one processor or processing core. The processor may for instance be a multi-core processor. A processor may also refer to a collection of processors within a single computer system or distributed amongst multiple computer systems. The term computing device should also be interpreted to possibly refer to a collection or network of computing devices each comprising a processor or processors. The computer executable code may be executed by multiple processors that may be within the same computing device or which may even be distributed across multiple computing devices.

Computer executable code may comprise machine executable instructions or a program which causes a processor to perform an aspect of the present invention. Computer executable code for carrying out operations for aspects of the present invention may be written in any combination of one or more programming languages, including an object oriented programming language such as Java, Smalltalk, C++ or the like and conventional procedural programming languages, such as the “C” programming language or similar programming languages and compiled into machine executable instructions. In some instances the computer executable code may be in the form of a high level language or in a pre-compiled form and be used in conjunction with an interpreter which generates the machine executable instructions on the fly.

The computer executable code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described with reference to flowchart illustrations and/or block diagrams of methods, apparatus (systems) and computer program products according to embodiments of the invention. It is understood that each block or a portion of the blocks of the flowchart, illustrations, and/or block diagrams, can be implemented by computer program instructions in form of computer executable code when applicable. It is further under stood that, when not mutually exclusive, combinations of blocks in different flowcharts, illustrations, and/or block diagrams may be combined. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

A ‘user interface’ as used herein is an interface which allows a user or operator to interact with a computer or computer system. A ‘user interface’ may also be referred to as a ‘human interface device.’ A user interface may provide information or data to the operator and/or receive information or data from the operator. A user interface may enable input from an operator to be received by the computer and may provide output to the user from the computer. In other words, the user interface may allow an operator to control or manipulate a computer and the interface may allow the computer indicate the effects of the operator's control or manipulation. The display of data or information on a display or a graphical user interface is an example of providing information to an operator. The receiving of data through a keyboard, mouse, trackball, touchpad, pointing stick, graphics tablet, joystick, gamepad, webcam, headset, pedals, wired glove, remote control, and accelerometer are all examples of user interface components which enable the receiving of information or data from an operator.

A ‘hardware interface’ as used herein encompasses an interface which enables the processor of a computer system to interact with and/or control an external computing device and/or apparatus. A hardware interface may allow a processor to send control signals or instructions to an external computing device and/or apparatus. A hardware interface may also enable a processor to exchange data with an external computing device and/or apparatus. Examples of a hardware interface include, but are not limited to: a universal serial bus, IEEE 1394 port, parallel port, IEEE 1284 port, serial port, RS-232 port, IEEE-488 port, Bluetooth connection, Wireless local area network connection, TCP/IP connection, Ethernet connection, control voltage interface, MIDI interface, analog input interface, and digital input interface.

A ‘display’ or ‘display device’ as used herein encompasses an output device or a user interface adapted for displaying images or data. A display may output visual, audio, and or tactile data. Examples of a display include, but are not limited to: a computer monitor, a television screen, a touch screen, tactile electronic display, Braille screen,

Cathode ray tube (CRT), Storage tube, Bi-stable display, Electronic paper, Vector display, Flat panel display, Vacuum fluorescent display (VF), Light-emitting diode (LED) displays, Electroluminescent display (ELD), Plasma display panels (PDP), Liquid crystal display (LCD), Organic light-emitting diode displays (OLED), a projector, and Head-mounted display.

Magnetic Resonance (MR) data is defined herein as being the recorded measurements of radio frequency signals emitted by atomic spins using the antenna of a Magnetic resonance apparatus during a magnetic resonance imaging scan. Magnetic resonance data is an example of medical image data. A Magnetic Resonance Imaging (MRI) image is defined herein as being the reconstructed two or three dimensional visualization of anatomic data contained within the magnetic resonance imaging data. This visualization can be performed using a computer.

In one aspect the invention provides for a magnetic resonance system for acquiring magnetic resonance data from a subject within a measurement zone. In different examples the magnetic resonance system may take different forms. For example in one case the magnetic resonance system could be an NMR spectrometer. In another case the magnetic resonance system could be a magnetic resonance imaging system. In the case where the magnetic resonance system is an NMR spectrometer the subject for example could be a chemical subject within a receptacle of some type which is placed within the measurement zone. The magnetic resonance system comprises a magnet for generating a main magnetic field within the measurement zone.

The magnetic resonance system further comprises a magnetic field gradient system for generating a gradient magnetic field within the measurement zone in at least one direction by supplying current to a set of magnetic gradient coils for each of the at least one direction. That is to say there will be a set of magnetic gradient coils for each of the directions in which a gradient magnetic field is generated. In magnetic resonance imaging systems there are typically three orthogonal sets of magnetic gradient coils. In the case of an NMR spectrometer there may be one, two or three sets of magnetic gradient coils.

The magnetic resonance system further comprises a memory for storing machine-executable instructions. The memory further stores pulse sequence commands. The pulse sequence commands cause the magnetic resonance system to acquire the magnetic resonance data according to a magnetic resonance fingerprinting technique. The pulse sequence commands specify a train of pulse sequence repetitions. This may also be interpreted that the pulse sequence commands specify a sequence or train of pulse sequence repetitions to be performed by the magnetic resonance imaging system. Each pulse sequence repetition has a fixed repetition time. That is to say each of the pulse repetitions has the same duration. Each pulse sequence repetition comprises either a radio-frequency pulse or a sampling event occurring at a fixed delay from the start of the pulse sequence repetition. Within each pulse sequence repetition either a radio-frequency pulse or a sampling event occurs but not both.

In many cases the fixed delay will be equal to the duration of the pulse sequence repetition and RF pulse or the sampling event will occur at the end of the pulse sequence repetition. However, there are different ways in which one could measure when a particular pulse sequence repetition starts or ends. Therefore the fixed delay is a means of expressing these different ways of interpreting when a pulse sequence repetition starts or begins. The radio-frequency pulse or sampling event happens so that they are at the same time within the pulse sequence repetition every time. The radio-frequency pulse is chosen from a distribution of radio-frequency pulses. The distribution of radio-frequency pulses causes magnetic spins to rotate to a distribution of flip angles. The pulse sequence commands specify the application of gradient magnetic fields in the at least one direction by controlling the supplied current to the set of gradient coils. The pulse sequence repetition may also have a predetermined (chosen) basic time unit which may arbitrarily include an RF excitation pulse or signal read-out. The basic time unit is the smallest time unit in which events, like RF excitations and signal read-outs (acquisitions) take place. Successive basic time units may include the same of different events and the succession of basic time units may or may not have a self-repeating unit (which would define the sequence's repetition time). However, there may be (pseudo-random) non-repetitive succession of the basic time units with different events.

For each of the set of magnetic gradient coils the integral of the current supplied is a constant for each fixed repetition time. The radio-frequency pulses are chosen from the distribution of radio-frequency pulses so that a variety of properties of the subject can be tested using the magnetic resonance fingerprinting technique. The magnetic resonance system comprises a processor for controlling the magnetic resonance system. A processor herein is used to encompass one or more processors and also controllers. Execution of the machine-executable instructions causes the processor to acquire the magnetic resonance data by controlling the magnetic resonance system with the pulse sequence commands.

Execution of the machine-executable instructions further cause the processor to calculate the abundance of each of a set of predetermined substances by comparing the magnetic resonance data with a magnetic resonance fingerprinting dictionary. The magnetic resonance fingerprinting dictionary contains a listing of calculated magnetic resonance signals in response to execution of the pulse sequence commands for a set of predetermined substances. Typically when the magnetic resonance fingerprinting technique is performed for a particular pulse sequence which defines when all of the sampling events occur and when all of the radio-frequency pulses occur. The sequence of radio-frequency pulses which are selected from the distribution of radio-frequency pulses is also defined. Very typically the magnetic resonance fingerprinting dictionary is tailored to the specific pulse sequence commands that are used. By comparing the magnetic resonance data to the magnetic resonance fingerprinting dictionary it can then be for example inferred which of and in which quantity the predetermined substances are within various voxels or volumes measured by the magnetic resonance system.

The method may have the advantage that the magnetic resonance fingerprinting technique is less susceptible to inhomogeneities in the B0 or main magnetic field within the measurement zone. The particular pulse sequence used uses the combination of the repetition times and the specification of the integral of the current supplied for the gradients results in a method which reduces the dependence of the measurement on the B0 inhomogeneity. This may have benefits in particular for magnetic resonance imaging. This may also be beneficial for nuclear magnetic resonance instruments or NMR spectrometers by adding one or more gradient coils. The gradient coil for the NMR spectrometer would not be used for spatial encoding but would be used instead to reduce the effects of the B0 inhomogeneity in the main magnetic field.

The magnetic resonance fingerprinting dictionary contains a listing of calculated magnetic resonance signals in response to execution of the pulse sequence commands for a set of predetermined substances.

When the pulse sequence commands are executed the pulse sequence repetitions are executed one-by-one. This leads to data being acquired for each pulse sequence repetition during the sampling time. The magnetic resonance fingerprinting dictionary contains the expected magnetic resonance signal for a particular substance. The measured signal is a linear combination of the magnetic resonance signals from the difference substances contained in a voxel. Depending on the voxel size there may be one or more substances in a voxel. In the magnetic resonance fingerprinting technique a possible composition of different substances is considered. The possible fingerprint for each of the substances is compared to the actual measured substance and the composition of the substance can be resolved using the magnetic resonance fingerprinting dictionary.

Normally, when a magnetic resonance fingerprinting dictionary is calculated, inhomogeneities in the magnetic field need to be taken into account. If the voxel size is small compared to the spatial field variations, a dictionary including calculated signal responses for a large number of different magnetic fields can provide a sufficiently good match. A larger voxel size may result in the fingerprint being essentially blurred for each of the set of predetermined substances. The use of the above mentioned pulse sequence commands may reduce the effect of the B0 inhomogenties on the magnetic resonance fingerprinting technique.

In another embodiment the radio-frequency pulse or the sampling event is centered at the time of the fixed delay. That is to say that the center of the radio-frequency pulse or the midpoint of the acquisition time of the sampling event has its location at the time of the fixed delay.

It should also be noted that the integral the current supplied being constant for each fixed repetition time for each of the set of magnetic gradient coils is equivalent to setting that the integral of the gradient magnetic field strength in a particular direction is a constant for each pulse repetition time. This is because the gradient coil current and the magnetic field strength are proportional. A constant integral supplied current within a time period is therefore equivalent to an integral of the magnetic field strength in a particular direction or for that particular coil within that same time period.

For example the text wherein the pulse sequence commands specify the application of gradient magnetic fields in the at least one direction by controlling the supplied current to the set of gradient coils and wherein for each of the sets of magnetic gradient coils the integral of the current supplied is a constant for each fixed repetition time may be replaced with the text wherein the pulse sequence commands specify the application of gradient magnetic fields in the at least one direction by controlling the supplied current to the set of gradient coils such that the integral of the gradient magnetic field strength over time in each of the at least one direction is a constant for each fixed repetition time or for each basic time unit.

The pulse sequence commands may contain instructions to perform the measurement of the magnetic resonance data at varying repetition times, varying flip angles and varying measurement times per pulse repetition. This may provide a useful distribution of pulse times that provide a good sampling and allow matching of the different components to the magnetic resonance fingerprinting dictionary. In more detail, magnetic resonance finger printing techniques include to record the temporal signal evolution of the magnetic resonance signal. The magnetic resonance signals are generated by an acquisition sequence including RF pulses and gradient pulses that has one or several variable elements. These variable element(s) are varied over the progression in time of the acquisition sequence. The recorded signal evolutions are compared to simulated evolutions of signals using the same acquisition sequence. The simulation may be done on the basis of the Bloch equations. The comparison of the measured signal evolutions to the simulated references may be done on the basis of a dictionary approach. The MR fingerprinting technique is sensitive to variations of tissue and material parameters. An insight to the MR fingerprinting techniques is that for different materials or tissues, there are unique signal evolutions that are representative for the material or tissue. The magnetic fingerprinting techniques have temporal and partial incoherence due to the variation of the acquisition parameters, such as flip angle, RF phases, repetition time and k-space sampling patterns in a pseudorandom manner. The magnetic fingerprinting allows to sample more informative points along a longer signal evolution as compared to conventional magnetic resonance imaging methods in which the signal level reaches a steady-state level after some finite amount of time.

The sequence of RF pulses (flip angles), the repetition times etc, can be random or pseudorandom. In a pseudorandom sequence of RF pulses or in RF pulses selected from a distribution of possible RF pulses the sequence of the RF pulses may be chosen such that it maximizes its encoding power to achieve the highest diversity between the potential MR responses for the different species. A main point is that the pulse sequence comprises a range of repetition times and flip angles instead of single values. This may be selected in a way that the resulting magnetic resonance signals are different for different tissues and resemble fingerprints.

The k-space sampling can be varied. For example uniform k-space sampling in one dimension, non-uniform k-space sampling in one dimension, and random k-space sampling in one dimension. When using a one dimensional slice selection, such as z-slice selection and sampling without x and y gradients (i.e., one whole z slice at a time), one might say that only a single point in k-space (the origin) is sampled. One could use the z gradient not for slice selection but for sampling k-space in z direction, again without x and y gradients. In this case, k-space would be one-dimensional and the sampling could be performed using a uniform or non-uniform distribution of points in k-space.

In another embodiment the pulse sequence comprises a train of pulse repetitions. Each pulse repetition of the train of the pulse repetitions may have a pseudo random distribution, a preselected duration from distribution of durations, or a pseudorandom duration. The preselected duration may be selected from the distribution such that the resulting train of RF pulses appears to be random or pseudo-random, but may be chose to also optimize other properties. For example as already mentioned above, the RF pulses may be chosen such that they maximize the sequence's encoding power to achieve the highest diversity between the potential MR responses for the different species. More in particular, the pulse sequence may have a random alternation of basic time units with an RF excitation or a signal read out. A random number of basic time units with RF excitations may alternate with a random number of basic time units with signal read outs. In another embodiment the magnetic resonance system is a magnetic resonance imaging system. The measurement zone is an imaging zone. The gradient system is configured for generating the gradient magnetic field in three orthogonal directions. In this case three sets of magnetic gradient coils are used. The magnetic field gradient system is configured for additionally generating a phase encoding gradient magnetic field within the measurement zone to spatially encode the magnetic resonance data in the three directions during the sampling event. The spatial encoding divides the magnetic resonance data into discreet voxels.

The main magnetic field is often also referred to as the B0 magnetic field. The pulse sequence commands further comprise instructions to control the magnetic field gradient system for performing spatial encoding of the magnetic resonance data during acquisition of the magnetic resonance data. The spatial encoding divides the magnetic resonance data into discrete voxels. This embodiment may be beneficial because it may provide a means for determining the spatial result composition of a subject more rapidly.

In another embodiment the pulse sequence commands specify that the phase encoding gradients are fully balanced about each sampling event. Stating that a phase encoding gradient is fully balanced is equivalent to saying that the total gradient area is 0. By total gradient area this could be interpreted as for example the current supplied to a particular gradient coil. Since the total gradient area is 0, this does not affect the integral of the current supplied being a constant for each fixed repetition time or basic time units of the individual repetitions.

In another embodiment, the pulse sequence is arranged as a spoiled gradient echo, optionally pseudo T1-spoiled sequence. The spoiled gradient echo MRF sequence has a defined inter-repetitions phase accumulation. All transverse magnetization is spoiled within each repetition so that only signal built-up along coherent pathways, i.e. FID, stimulated echoes and conjugate stimulated echoes are sampled. The pseudo T1spoiled MRF sequence has a distinct and finite number of contributing coherences. This adds to the sampled signals being insensitive to main magnetic field inhomogeneities, so that the MRF encoding space is reduced because MRF library entries do not have to be listed as dependent on the main field variations.

Further, the MRF sequence of the invention formed as a gradient spoiled, optional pseudo T1 spoiled pulse sequence employs variations of the flip angle and the sequence repetition time. The net gradient area (time integral) is set proportional to the sequence repetition item. Dephasing occurs between successive dephasing states, i.e. that there is sufficient dephasing between successive (sets of) repetitions. The sequence repetition time may be selected as an integer of the (base) fixed repetition time or basic time unit of the individual repetitions. Dummy repetitions void of RF excitations and signal sampling may be inserted to further vary the sequence repetition time. These aspects of the invention involve

Use of “pseudo T1-”spoiled MRF sequences that allow a significant simplification of the Bloch simulation (one can assume that only a distinct and finite number of coherences that contribute in a very defined way to the MRF signal detected).

Making the MRF acquisition more efficient by reducing the necessary MRF encoding space (no off-resonances need to be encoded), the results are independent of the off-resonance.

To allow using the phase of the RF pulse to become an additional encoding element using dedicated “RF spoiling” schemes allowing for efficient MRF sampling and reliable signal matching.

In another embodiment the spatial encoding is one dimensional. The discrete voxels are a set of discrete slices. The method further comprises the step of dividing the magnetic resonance data into the set of slices. The abundance of each of the set of predetermined substances is calculated within each of the set of slices by comparing the magnetic resonance data for each of the set of slices with the magnetic resonance fingerprinting dictionary.

In another embodiment the spatial encoding is performed by controlling the magnetic field gradient system to produce a constant magnetic field gradient in a predetermined direction during the execution of the pulse sequence.

In another embodiment the spatial encoding is performed by controlling the magnetic field gradient system to produce a one-dimensional readout gradient at least partially during the sampling event.

In another embodiment the spatial encoding is three-dimensional. The spatial encoding is performed by controlling the magnetic field gradient system to produce a three-dimensional readout gradient at least partially during the sampling event.

In another embodiment the spatial encoding is performed as non-Cartesian spatial encoding. The spatial encoding is performed by controlling the magnetic field gradient system to produce a readout gradient during the sampling event which samples k-space in a non-Cartesian order.

In another embodiment the calculation of the abundance of each of the predetermined tissue types within each of the discrete voxels is performed by comparing the magnetic resonance data for each of the discreet voxels with the magnetic resonance fingerprinting dictionary is performed by first expressing each magnetic resonance signal of the magnetic resonance data as a linear combination of the signal from each of the set of predetermined substances. And second by determining the abundance of each of the set of predetermined substances by solving the linear combination using a minimization technique.

In another embodiment the magnetic resonance system is a nuclear magnetic resonance spectrometer. This is also known as an NMR spectrometer.

In another embodiment execution of the machine-executable instructions further causes the processor to calculate the magnetic resonance fingerprinting dictionary. The actual calculation of the magnetic resonance fingerprinting dictionary may be performed by any number of a variety of techniques for modeling the NMR signal. For example it may be modeled by adding up a large number of single spins calculated using the so called Bloch equations. The dictionary is created by calculating the expected NMR signal from a voxel for a specific set of substance parameters and the particular MR sequence that is specified by the pulse sequence commands.

In another embodiment the magnetic resonance fingerprinting dictionary is calculated by modeling each of the predetermined substances using an extended phase graph formulation. The extended phase graph formulation is for example described in Weigel, M. (2015), Extended phase graphs: Dephasing, RF pulses, and echoes—pure and simple. J. Magn. Reson. Imaging, 41: 266-295. doi: 10.1002/jmri.24619 and is also described in Scheffler, K. (1999), A pictorial description of steady-states in rapid magnetic resonance imaging. Concepts Magn. Reson., 11: 291-304. doi: 10.1002/(SICI)1099-0534(1999)11:5<291::AID-CMR2>3.0.CO; 2-J.

In another embodiment the pulse sequence commands specify the reading out of the k-space center at the fixed delay.

In another embodiment, execution of the instructions further cause the processor to repeat measurement of the magnetic resonance data of at least one calibration phantom. The at least one calibration phantom comprises a known volume of at least one of the set of predetermined substances.

When used with a system that measures the magnetic resonance data along one dimension, each of the calibration phantoms may have a calibration axis. In this case the at least one calibration phantom comprises a known volume of at least one of the set of predetermined substances when the calibration axis is aligned with the predetermined direction. In other cases for instance when the calibration phantom is used in a system where a three-dimensional or two-dimensional imaging is made, the predetermined substances may be distributed uniformly with known concentration within the calibration phantom.

In another aspect the invention provides for a computer program product containing machine-executable instructions for execution by a processor controlling the magnetic resonance system for acquiring magnetic resonance data from a subject within a measurement zone. The magnetic resonance system comprises a magnet for generating a main magnetic field within the measurement zone. The magnetic resonance system further comprises a magnetic field gradient system for generating a gradient magnetic field within the measurement zone in at least one direction by supplying a current to a set of magnetic gradient coils for each of the at least one direction. Execution of the machine-executable instructions causes the processor to acquire the magnetic resonance data by controlling the magnetic resonance system with pulse sequence commands.

The pulse sequence commands cause the magnetic resonance system to acquire the magnetic resonance data according to a magnetic resonance fingerprinting technique. The pulse sequence commands specify a train of pulse sequence repetitions. Each pulse sequence repetition has a fixed repetition time. Each pulse sequence repetition comprises either a radio-frequency pulse or a sampling event occurring at the fixed delay from the start of the pulse sequence repetition. The radio-frequency pulse is chosen from a distribution of radio-frequency pulses. The distribution of radio-frequency pulses causes magnetic spins to rotate to a distribution of flip angles. The pulse sequence commands specify the application of gradient magnetic fields in the at least one direction by controlling the supplied current to the set of gradient coils. For each of the set of magnetic gradient coils the integral of current supplied is a constant for each fixed repetition time.

Execution of the instructions further cause the processor to calculate the abundance of each of the set of predetermined substances by comparing the magnetic resonance data with the magnetic resonance fingerprinting dictionary. The magnetic resonance fingerprinting dictionary contains a listing of calculated magnetic resonance signals and responds to execution of the pulse sequence commands for a set of predetermined substances.

In another aspect the invention provides for a method of operating a magnetic resonance system to acquire magnetic resonance data from a subject within a measurement zone. The magnetic resonance system comprises a magnet for generating a main magnetic field within the measurement zone. The magnetic resonance system further comprises a magnetic field gradient system for generating a gradient magnetic field within the measurement zone is at least one direction by supplying current to a set of magnetic gradient coils for each of the at least one direction. The method comprises the step of acquiring the magnetic resonance data by controlling the magnetic resonance system with pulse sequence commands.

The pulse sequence commands cause the magnetic resonance system to acquire the magnetic resonance data according to a magnetic resonance fingerprinting technique. The pulse sequence commands specify a train of pulse sequence repetitions. Each pulse sequence repetition has a fixed repetition time. Each pulse sequence repetition comprises either a radio-frequency pulse or a sampling event occurring at a fixed delay from the start of the pulse sequence repetition. The radio-frequency pulse is chosen from a distribution of radio-frequency pulses. The distribution of radio-frequency pulses causes magnetic spins to rotate to a distribution of flip angles. The pulse sequence commands specify the application of gradient magnetic fields in the at least one direction by controlling the supplied current to the set of gradient coils. For each of the set of magnetic gradient coils the integral of the current supplied is a constant for each fixed repetition time.

The method further comprises calculating the abundance of each of the set of predetermined substances by comparing the magnetic resonance data with the magnetic resonance fingerprinting dictionary. The magnetic resonance fingerprinting dictionary contains a listing of calculated magnetic resonance signals in response to execution of the pulse sequence commands for a set of predetermined substances.

It is understood that one or more of the aforementioned embodiments of the invention may be combined as long as the combined embodiments are not mutually exclusive.

### BRIEF DESCRIPTION OF THE DRAWINGS

In the following preferred embodiments of the invention will be described, by way of example only, and with reference to the drawings in which:

FIG. 1 illustrates an example of a magnetic resonance imaging system;

FIG. 2 illustrates a method of operating the magnetic resonance imaging system of FIG. 1;

FIG. 3 illustrates a portion of a pulse sequence;

FIG. 4 illustrates a further portion of a pulse sequence;

FIG. 5 illustrates a train of pulse sequence repetitions;

FIG. 6 shows the phase graph for the pulse sequence shown in FIG. 5;

FIG. 7 shows an alternative representation of the pulse sequence such as is illustrated in FIGS. 5 and 6; and

FIGS. 8 and 9 show an example of a magnetic resonance fingerprinting dictionary.

### DETAILED DESCRIPTION OF THE EMBODIMENTS

Like numbered elements in these figures are either equivalent elements or perform the same function. Elements which have been discussed previously will not necessarily be discussed in later figures if the function is equivalent.

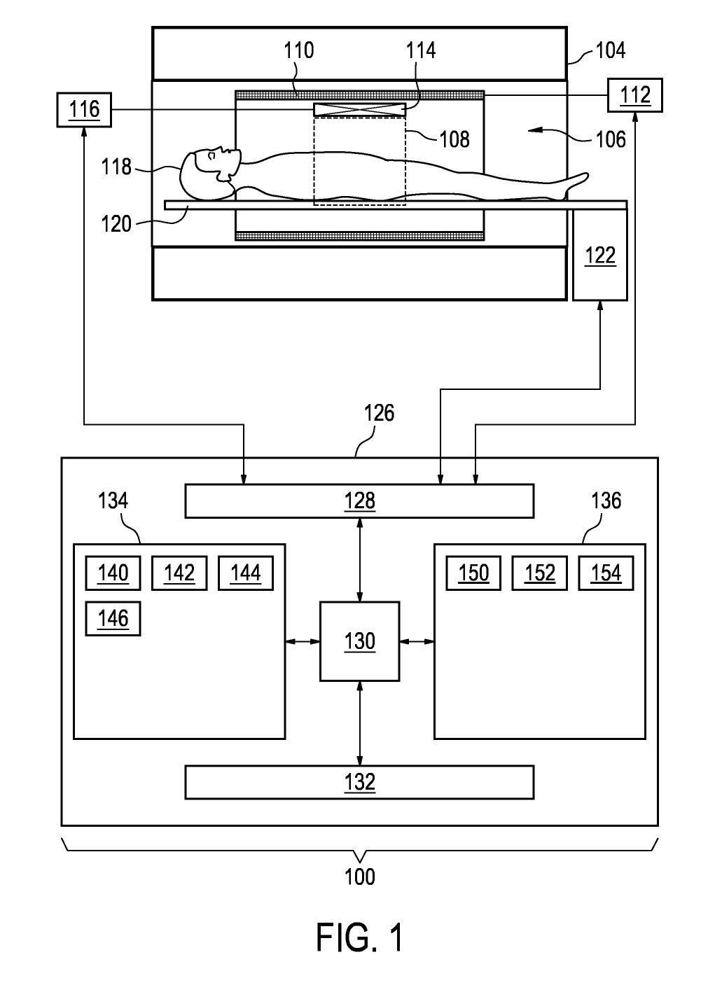

FIG. 1 shows an example of a magnetic resonance imaging system 100 with a magnet 104. The magnet 104 is a superconducting cylindrical type magnet 104 with a bore 106 through it. The use of different types of magnets is also possible; for instance it is also possible to use both a split cylindrical magnet and a so called open magnet. A split cylindrical magnet is similar to a standard cylindrical magnet, except that the cryostat has been split into two sections to allow access to the iso-plane of the magnet, such magnets may for instance be used in conjunction with charged particle beam therapy. An open magnet has two magnet sections, one above the other with a space in-between that is large enough to receive a subject: the arrangement of the two sections area similar to that of a Helmholtz coil. Open magnets are popular, because the subject is less confined. Inside the cryostat of the cylindrical magnet there is a collection of superconducting coils. Within the bore 106 of the cylindrical magnet 104 there is an imaging zone 108 where the magnetic field is strong and uniform enough to perform magnetic resonance imaging.

Within the bore 106 of the magnet there is also a set of magnetic field gradient coils 110 which is used for acquisition of magnetic resonance data to spatially encode magnetic spins within the imaging zone 108 of the magnet 104. The magnetic field gradient coils 110 connected to a magnetic field gradient coil power supply 112. The magnetic field gradient coils 110 are intended to be representative. Typically magnetic field gradient coils 110 contain three separate sets of coils for spatially encoding in three orthogonal spatial directions. A magnetic field gradient power supply supplies current to the magnetic field gradient coils. The current supplied to the magnetic field gradient coils 110 is controlled as a function of time and may be ramped or pulsed.

Adjacent to the imaging zone 108 is a radio-frequency coil 114 for manipulating the orientations of magnetic spins within the imaging zone 108 and for receiving radio transmissions from spins also within the imaging zone 108. The radio frequency antenna may contain multiple coil elements. The radio frequency antenna may also be referred to as a channel or antenna. The radio-frequency coil 114 is connected to a radio frequency transceiver 116. The radio-frequency coil 114 and radio frequency transceiver 116 may be replaced by separate transmit and receive coils and a separate transmitter and receiver. It is understood that the radio-frequency coil 114 and the radio frequency transceiver 116 are representative. The radio-frequency coil 114 is intended to also represent a dedicated transmit antenna and a dedicated receive antenna. Likewise the transceiver 116 may also represent a separate transmitter and receivers. The radio-frequency coil 114 may also have multiple receive/transmit elements and the radio frequency transceiver 116 may have multiple receive/transmit channels.

The subject support 120 is attached to an optional actuator 122 that is able to move the subject support and the subject 118 through the imaging zone 108. In this way a larger portion of the subject 118 or the entire subject 118 can be imaged. The transceiver 116, the magnetic field gradient coil power supply 112 and the actuator 122 are all see as being connected to a hardware interface 128 of computer system 126. The computer storage 134 is shown as containing pulse sequence commands 140 for performing a magnetic resonance fingerprinting technique.

The pulse sequence commands cause the magnetic resonance system to acquire the magnetic resonance data according to a magnetic resonance fingerprinting technique. The pulse sequence commands specify a train of pulse sequence repetitions. Each pulse sequence repetition has a fixed repetition time. Each pulse sequence repetition comprises either a radio frequency pulse or a sampling event occurring at a fixed delay from the start of the pulse sequence repetition, wherein the radio frequency pulse is chosen from a distribution of radio frequency pulses. The distribution of radio frequency pulses cause magnetic spins to rotate to a distribution of flip angles. The pulse sequence commands specify the application of gradient magnetic fields in the at least one direction by controlling the supplied current to the set of gradient coils. For each of the set of magnetic gradient coils the integral of current supplied is a constant for each fixed repetition time.

The computer storage 134 is further shown as containing magnetic resonance data 142 that was acquired using the pulse sequence commands 140 to control the magnetic resonance imaging system 100. The computer storage 134 is further shown as containing a magnetic resonance fingerprinting dictionary 144. The computer storage is further shown as containing a magnetic resonance image 146 that was reconstructed using the magnetic resonance data 142 and the magnetic resonance fingerprinting dictionary 144.

The computer memory 136 contains a control module 150 which contains such code as operating system or other instructions which enables the processor 130 to control the operation and function of the magnetic resonance imaging system 100.

The computer memory 136 is further shown as containing a magnetic resonance fingerprint dictionary generating module 152. The fingerprint generating module 152 may model one or more spins using the Bloch equation for each voxel to construct the magnetic resonance fingerprinting dictionary 144. The computer memory 136 is further shown as containing an image reconstruction module that uses the magnetic resonance data 142 and the magnetic resonance fingerprinting dictionary 144 to reconstruct the magnetic resonance image 146. For example the magnetic resonance image 146 may be a rendering of the spatial distribution of one or more of the predetermined substances within the subject 118.

The example of FIG. 1 could be modified so that the magnetic resonance imaging system or apparatus 100 is equivalent to a Nuclear Magnetic Resonance (NMR) spectometer. Without gradient coils 110 and the gradient coil power supply 112 the apparatus 100 would perform a 0-dimensional measurement in the imaging zone 108.

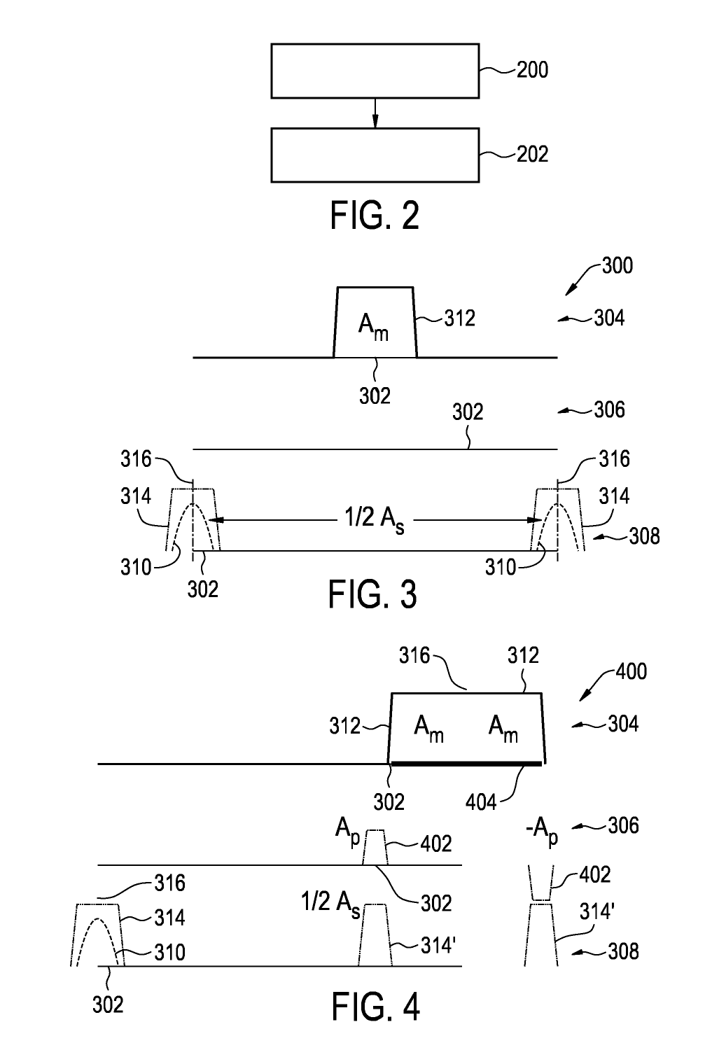

FIG. 2 shows a flowchart which illustrates a method of operating the magnetic resonance imaging system 100 of FIG. 1. First in step 200 the magnetic resonance data 142 is acquired by controlling the magnetic resonance imaging system with the pulse sequence commands 140. Next in step 202 the abundance of each of the set of the predetermined substances is calculated by comparing the magnetic resonance data 142 with the magnetic resonance fingerprinting dictionary 144. The abundance for instance may be plotted or displayed in the magnetic resonance image 146.

MR fingerprinting is a promising new approach to quantitative MRI. This invention disclosure describes a class of novel MR sequences which allow the necessary flexibility for MR fingerprinting but result in an MR signal that is independent of ΔB0 effects (effects due to inhomogenity of the B0 or main magnetic field). These sequences may avoid problems like signal loss due to intra-voxel dephasing, or having to include ΔB0 in the simulation of the MR fingerprinting dictionary as an unnecessary extra dimension. A great advantage of the described sequences is that they do not require 180-degree pulses, thereby avoiding SAR issues. The expected signals can easily be simulated using the extended phase graph (EPG) formalism, which allows calculating large dictionaries in reasonable time.

MR fingerprinting (MRF) is a novel approach to quantitative MRI. The traditional approach to MR imaging is based on repeating the same basic sequence building block many times for different phase-encoding steps to obtain all data necessary to reconstruct an image. In contrast, MR fingerprinting records the temporal evolution of the MR signal using a sequence that contains many variable elements (flip angle, TR . . . ). The magnetization properties (M0, T1, T2, . . . ) of the imaged object and the system parameters that affect the signal evolution are then obtained by comparing the acquired signal to a simulated signal evolution using the same sequence. Typically the simulations are carried out before the experiment for a large set of parameter combinations and then stored in a dictionary. When the measurement is performed, the object's properties are obtained by finding that signal evolution from the dictionary that best matches the acquired data.

The sequence for MR fingerprinting needs to be chosen such that it is sensitive to changes of those tissue/material parameters that are relevant for the clinical question in order to get high accuracy for these variables in the matching process. On the other hand, the sequence should not be sensitive to all other factors potentially influencing the MR signal to avoid including these variables as additional dimensions in the dictionary (leading to exponentially slow matching/simulation and potential ambiguities in matching).

One parameter that is usually of no clinical interest but can have an unfavourable influence on the MR signal is off-resonance (ΔB0). Examples may provide for a new class of new MR sequences that allow the necessary flexibility for MR fingerprinting but result in an MR signal independent of ΔB0 effects. These sequences avoid problems like signal loss due to intra-voxel dephasing, or having to include ΔB0 in the simulation of the MR fingerprinting dictionary as an unnecessary extra dimension.

Examples of the MR fingerprinting sequence may possibly be made insensitive against variations of the main field by imposing certain restrictions on the sequence objects. However, these restrictions leave enough flexibility to achieve the variations needed for MR fingerprinting:

Let T be the duration of a chosen basic time unit of the sequence. The sequence may have one or more of the following features:

1. RF pulses may only be placed at times that are integer multiples of T. Flip angles and phases of the RF pulses can be chosen arbitrarily.
2. The same total gradient area must be accumulated during each interval of T in all three main directions independently. (This requirement does not apply to the phase-encoding gradients, provided that they are fully balanced around each data acquisition.)
3. Data acquisition periods may be placed around integer multiples of T if there is no RF pulse at that time. (The k-space centre k=0 is always passed exactly at integer multiples of T.)

The length and gradient area requirements ensure that all magnetization states generated by the sequence can be modelled by a single set of equally spaced states in the extended phase graph formalism, which ensures an efficient refocussing of magnetization. It also guarantees that the additional phase due to off-resonance is always exactly zero at integer multiples of T, i.e. in the center of each readout.

Since an echo is formed at all integer multiples of T it is advantageous to place data acquisition periods at all integer multiples of T that are not used by RF pulses to maximize the rate of information acquired about the object. I.e. one can characterize the fingerprinting sequence by the sequence of excitation (E) and acquisition (A). All sequences of these two letters describe a valid fingerprinting sequence that is insensitive to off-resonance (where, within each E there is the additional freedom of choosing flip angle and phase).

In the following, an example of a possible sequence is shown together with the corresponding phase-graph visualizing the formation of echoes. The two FIGS. 3 and 4 described below show a symbolic representation of an E segment (FIG. 3) and of an A segment (FIG. 4).

FIG. 3 shows a portion of a pulse sequence 300. The bars labeled 302 represent the fixed repetition time 302. There are three lines, the first line numbered 304 is used to specify readout gradients. The line numbered 306 indicates a space for specifying phase encoding gradients 306 and the line numbered 308 shows a place for specifying slice selection gradients and also the location of the RF pulse 310. In the example shown in FIG. 3 the pulse sequence 300 does not show phase encoding. A single readout gradient 312 is shown. In the example on line 308 there is a slice selection gradient 314 and an RF pulse 310 that occur at both the beginning and end of the fixed repetition time 302. In this example there is a center line 316 about which the slice selection gradient 314 and the RF pulse 310 are centered. The RF pulse 310 and the slice selection gradient 314 are shown as being divided into parts by the start and end of the fixed repetition time 302. This is however a bit artificial because the start and end of the fixed repetition time 302 can be shifted and the location of the center line 316 can be interpreted as a fixed delay from the start of the pulse sequence repetition. That is to say FIG. 3 can be rearranged such that the entire RF pulse 310 and the slice selection gradient 314 are within a single fixed repetition time 302. FIG. 3 represents a pulse sequence repetition where an RF pulse is applied at the delay 316.

FIG. 4 shows a further example of a portion of a pulse sequence 400. FIG. 4 illustrates a pulse sequence repetition where a sampling event 404 occurs. In the beginning of the fixed repetition time 302 there is an RF pulse 310. At the end of the fixed repetition time 302 there is no RF pulse. Instead there is a readout gradient 312 applied symmetrically about the fixed delay 316′. There is also a phase encoding gradient 402 which is also symmetric about the fixed delay 316′. Likewise around the fixed delay 316′ the slice selection gradient 314′ has been split into two symmetric parts. As with FIG. 4 the exact location of the fixed repetition time 302 can be adjusted such that all of the components of a particular pulse sequence repetition are within that fixed repetition time 302. Both the fixed delay 316 and 316′ are shown at the beginning and end of the fixed repetition time 302 that is displayed. However for example, the beginning of the fixed repetition time 302 could be shifted to be exactly between 316 and 316′. In this case the gradients 312, 402 and 314′ could all be contained within the same fixed repetition time 302.

In both FIGS. 3 and 4, the total areas in M 304, P 306, and S 308 during one T are: Am, 0, As. The total area of the read-out gradient is 2Am.

Longer sequences can be constructed by combining these elements (using also the A, E fragments):

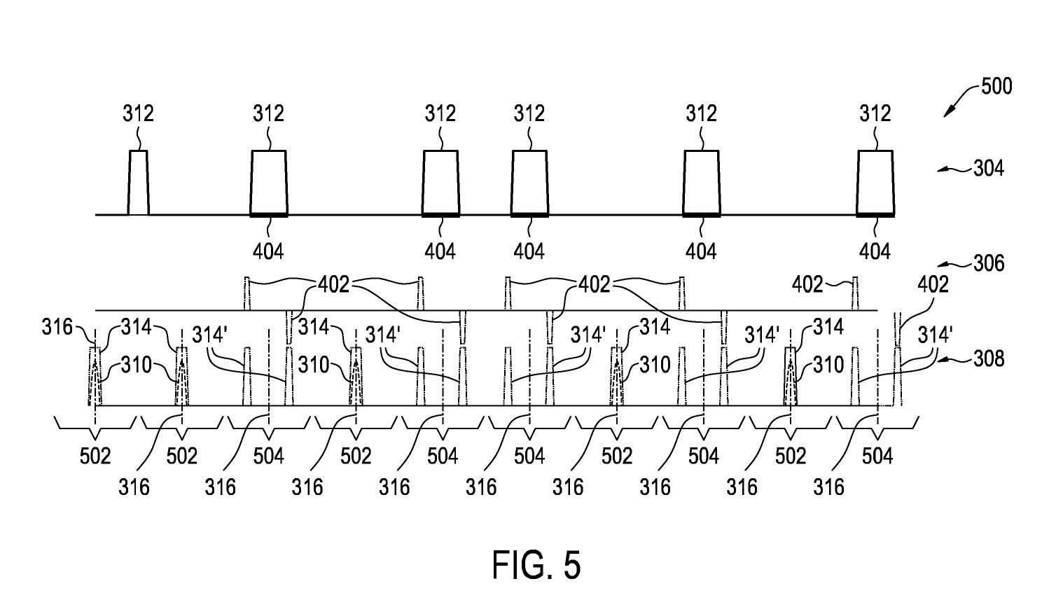

FIG. 5 shows a train 500 of pulse sequence repetitions. In this case the timeline has been divided into a number of portions that are equal duration. These correspond to the fixed repetition time. The fixed repetition times are labeled either 502 or 504. The fixed repetition time 502 corresponds to a pulse sequence repetition with a radio-frequency pulse at the fixed delay 316. The pulse sequence repetitions labeled 504 correspond to a pulse sequence repetition with a sampling event 404 centered at the fixed delay 316. The time periods in FIG. 5 are divided differently than FIGS. 3 and 4. It can be seen that the gradients 312, 402, 314, 314′ are all for a particular pulse sequence repetition contained within the respective pulse sequence repetition 502 or 504. FIG. 5 illustrates how the basic building blocks of the pulse sequence repetitions 502 or 504 can be used to string together to form pulse sequence commands that are useful for performing magnetic resonance fingerprinting.

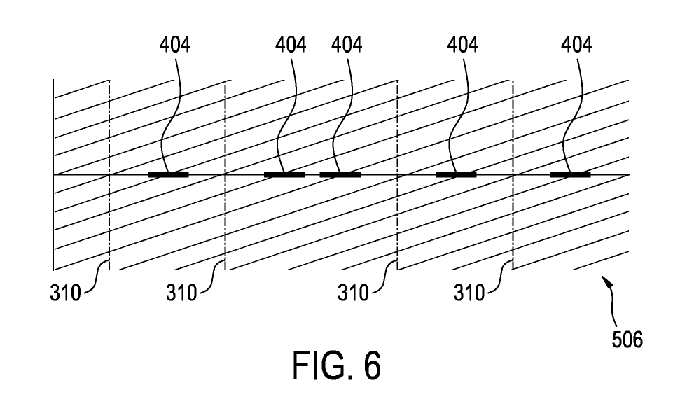

FIG. 6 shows the phase graph for the pulse sequence 500 shown in FIG. 5. The location of the RF pulses 310 and the sampling events 404 are labeled. The pulse sequence shown in FIG. 5 represents a randomized sequence. During each time unit or fixed repetition time the same gradient area is accumulated. The RF pulses have arbitrary flip angles and phases and may be placed at integer multiples of the fixed repetition time. In this example they are placed at the fixed delay 316. Echoes are then generated at all integer multiples of the fixed repetition time. The echoes are generated at the fixed delay 316. If there is no RF pulse present at the fixed delay 316 the echoes may be read out. The slanted lines 600 represent the states of the spin system in a phase graph basis. Not all states are shown and the evolution of some states is clipped at the upper and lower border of the image. The slope of the lines represents the acquisition of phase due to non-balanced gradients.

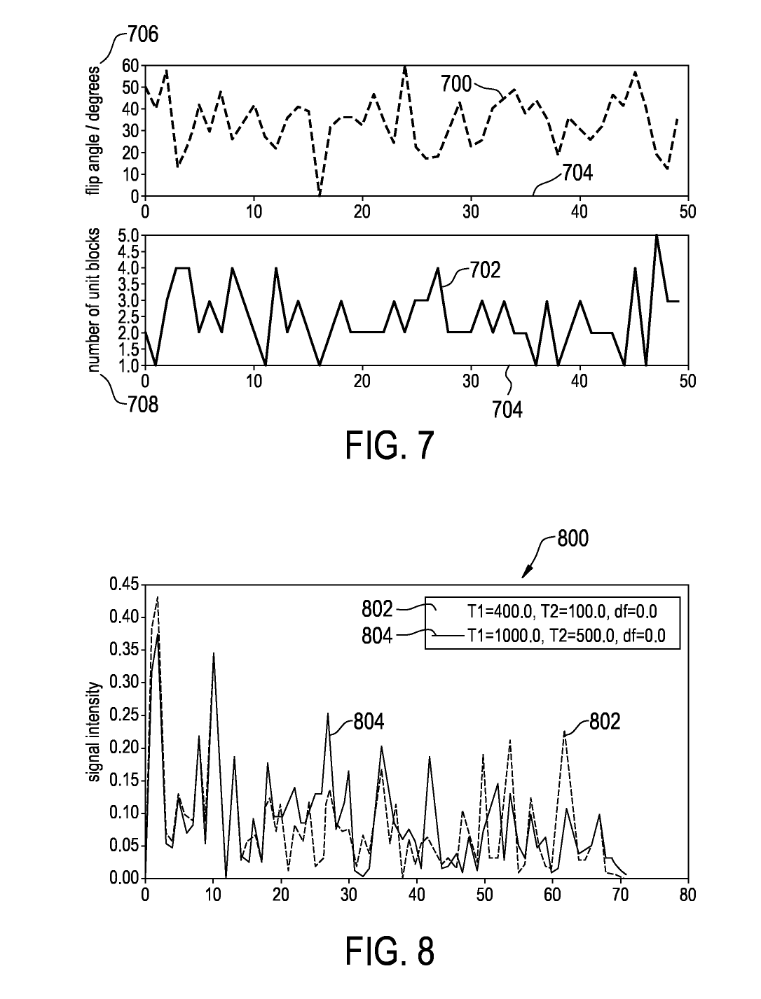

FIG. 7 shows an alternative representation of the pulse sequence such as is illustrated in FIGS. 5 and 6. FIG. 7 shows two plots. The upper plot 700 plots the distribution of the selected flip angles. The second plot or lower plot shows the number of steps 702 to wait until the next radio-frequency pulse is applied. The x-axis 704 is the number of pulse sequence repetitions 704. 706 and the y-axis in the top plot shows the selected flip angle. The lower y-axis 708 shows the number of unit blocks 708. The number of unit blocks corresponds to a pulse sequence repetition.

This sequence consists of 50 steps (shown on the x axis), where each step contains an integer number of unit blocks of time T (shown in the lower graph). At the start of each step, an RF pulse of random flip angle is applied (upper graph).

Steps with length n*T comprise 1 RF pulse and (n−1) measurements. Accordingly, the length of the resulting fingerprint signals differs from the number of sequence steps. The following graph shows an example of two different fingerprint signals calculated from the above sequence for different T1/T2 combinations. Such a set of calculated signals can be used as an MRF dictionary for comparison with a measurement.

FIG. 8 shows an example of a magnetic resonance fingerprinting dictionary 800. There is a first entry 802 and a second entry 804. In this example the dictionary 800 is calculated for a particular set of pulse sequence commands. Each entry 802, 804 represents the expected MR signal measured for two different materials. Material 802 has a T1 time of 400 ms and a T2 time of 100 ms. Material 2 804 has a T1 time of 1000 ms and a T2 time of 500 ms. Actual measured MR signals can be compared to the two dictionary entries 802, 804 and for example a linear combination of the two can be added to approximate the measured MR signal. In this way the relative ratios of the first material 802 and the second material 804 within a particular volume can be deducted.

Other aspects of the invention use spoiled gradient echo sequences, which include gradient and optional RF spoiling, to perform MR Fingerprinting. Spoiled sequences are characterized by a defined inter-TR phase accumulation (by off-resonance and gradient switching) and appropriate RF signal spoiling optionally used to achieve T1 weighting. Since all transverse magnetization is spoiled within each TR, only signals from discrete coherence pathways (essentially FIDs, spin echoes and stimulated echoes) superimpose coherently and contribute to the measured MR signal. Particularly, off-resonance effects are reduced to the T2* contrast specific for the chosen gradient echo time. Moreover, the calculation of the dictionary is vastly simplified, because only a countable number of coherences have to be tracked, instead of summing up contributions from multitudinous magnetic moments.

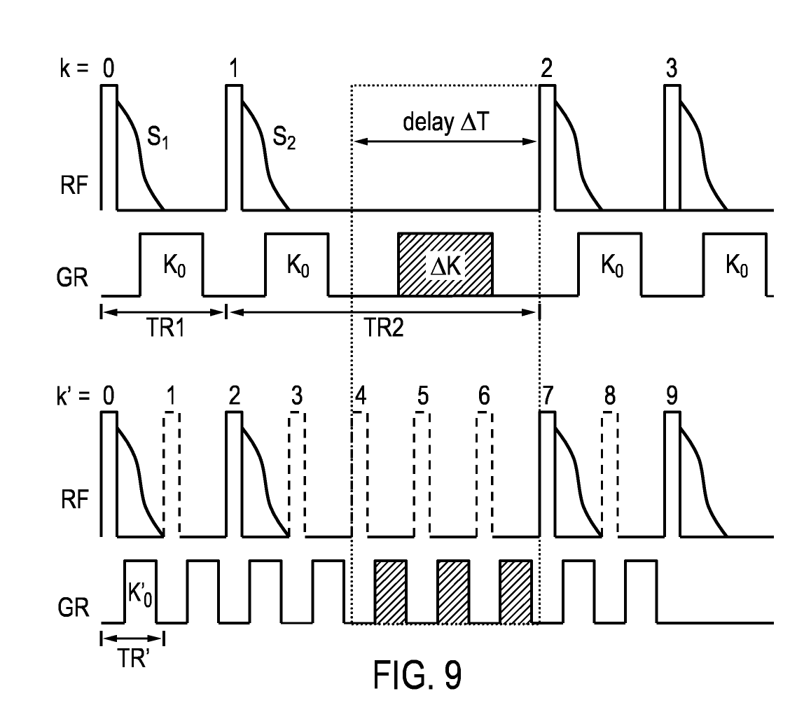

In an MRF acquisition, generally no steady state will be build-up, because the flip angle and the TR of the sequence will be varied by deliberate choice according to the chosen dictionary. While a varying flip angle αₖ is already covered in the framework of configuration theory a varying TR is not directly possible. Adding a simple variable delay to the end of each TR interval would lead to non-synchronous phase contributions from switched gradients and static gradients (i.e. off-resonance), making calculation (Bloch simulations) very difficult. Therefore, as a first requirement, the net gradient area of the switched gradients must be adjusted to be proportional to the corresponding TR. A second requirement arises from the fact that the different dephasing states are not allowed to mix. In other words, there must be always sufficient dephasing between neighboring dephasing states, ensuring that only state l=0 contributes to the measured signal. Otherwise, echoes with shifted “echo top” would overlap, causing serious artifacts, compromising MRF signal reception. This can be achieved by selecting the varying TR as an integer multiple of the base TR of the original sequence. In a practical implementation, both requirements can be met by introducing “dummy sequence modules” where both the RF excitation and acquisition is switched off (see FIG. 9).

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measures cannot be used to advantage. A computer program may be stored/distributed on a suitable medium, such as an optical storage medium or a solid-state medium supplied together with or as part of other hardware, but may also be distributed in other forms, such as via the Internet or other wired or wireless telecommunication systems. Any reference signs in the claims should not be construed as limiting the scope.

### LIST OF REFERENCE NUMERALS

100 magnetic resonance system
104 magnet
106 bore of magnet
108 measurement zone or imaging zone
110 magnetic field gradient coils
112 magnetic field gradient coil power supply
114 radio-frequency coil
116 transceiver
118 subject
120 subject support
122 actuator
124 predetermined direction
125 slices
126 computer system
128 hardware interface
130 processor
132 user interface
134 computer storage
136 computer memory
140 pulse sequence commands
142 magnetic resonance data
144 magnetic resonance fingerprinting dictionary
146 magnetic resonance image
150 control module
152 magnetic resonance fingerprint dictionary generating module
154 image reconstruction module
200 acquire the magnetic resonance data by controlling the magnetic resonance system with pulse sequence commands
202 calculate the abundance of each of a set of predetermined substances by comparing the magnetic resonance data with a magnetic resonance fingerprinting dictionary
300 portion of pulse sequence
302 fixed repetition time
304 readout
306 phase-encoding
308 slice selection
310 RF pulse
312 readout gradient
314 slice selection gradient
314′ slice selection gradient
316 fixed delay
316′ fixed delay
400 portion of pulse sequence
402 phase encoding gradient
404 sampling event
500 train of pulse sequence repetition
502 pulse sequence repetition with RF pulse
504 pulse sequence repetition with sampling event
600 combination of states
700 distribution of the selected flip angels
702 number of steps to wait until next RF pulse
704 number of pulse sequence repetitions
706 selected flip angle
708 number of unit blocks
800 magnetic resonance fingerprinting dictionary
802 first entry
804 second entry

1. A magnetic resonance system for acquiring a magnetic resonance data from a subject within a measurement zone, wherein the magnetic resonance system comprises:
a magnet for generating a main magnetic field within the measurement zone;
a magnetic field gradient system for generating a gradient magnetic field within the measurement zone in at least one direction by supplying current to a set of magnetic gradient coils for each of the at least one direction;
a memory for storing machine executable instructions, and pulse sequence commands, wherein the pulse sequence commands cause the magnetic resonance system to acquire the magnetic resonance data according to a magnetic resonance fingerprinting technique, wherein the pulse sequence commands specify a train of pulse sequence repetitions, wherein each pulse sequence repetition has a fixed repetition time, wherein each pulse sequence repetition comprises either a radio frequency pulse or a sampling event occurring at a fixed delay from the start of the pulse sequence repetition, wherein the radio frequency pulse is chosen from a distribution of radio frequency pulses, wherein the distribution of radio frequency pulses cause magnetic spins to rotate to a distribution of flip angles, wherein the pulse sequence commands specify the application of gradient magnetic fields in the at least one direction by controlling the supplied current to the set of gradient coils, wherein for each of the set of magnetic gradient coils the integral of current supplied is a constant for each fixed repetition time,
a processor for controlling the magnetic resonance system, wherein execution of the machine executable instructions causes the processor to:
acquire the magnetic resonance data by controlling the magnetic resonance system with pulse sequence commands; and
calculate an abundance of each of a set of predetermined substances by comparing the magnetic resonance data with a magnetic resonance fingerprinting dictionary, wherein the magnetic resonance fingerprinting dictionary contains a listing of calculated magnetic resonance signals in response to execution of the pulse sequence commands for a set of predetermined substances.

2. The magnetic resonance system of claim 1, wherein the magnetic resonance system is a magnetic resonance imaging system, wherein the measurement zone is an imaging zone, wherein the gradient system is configured for generating the gradient magnetic field in three orthogonal directions, wherein the magnetic field gradient system is configured for additionally generating a phase encoding gradient magnetic field within the measurement zone to spatially encode the magnetic resonance data in the three directions during the sampling event, wherein the spatial encoding divides the magnetic resonance data into discrete voxels.

3. The magnetic resonance system of claim 2, wherein the pulse sequence commands specify that the phase encoding gradients are fully balanced about each sampling event.

4. The magnetic resonance system of claim 2, wherein the spatial encoding is one-dimensional, wherein the discrete voxels are a set of discrete slices, wherein the method further comprises the step of dividing the magnetic resonance data into the set of slices, wherein the abundance of each of a set of predetermined substances is calculated within each of the set of slices by comparing the magnetic resonance data for each of the set of slices with the magnetic resonance fingerprinting dictionary.

5. The magnetic resonance system of claim 2, wherein the spatial encoding is performed by controlling the magnetic field gradient system to produce a constant magnetic field gradient in a predetermined direction during the execution of the pulse sequence.

6. The magnetic resonance system of claim 2, wherein the spatial encoding is performed by controlling the magnetic field gradient system to produce a one dimensional readout gradient at least partially during the sampling event.

7. The magnetic resonance system of claim 2, wherein the spatial encoding is three dimensional, wherein the spatial encoding is performed by controlling the magnetic field gradient system to produce a three dimensional readout gradient at least partially during the sampling event.

8. The magnetic resonance system of claim 2, wherein the spatial encoding is performed as non-Cartesian spatial encoding, wherein the spatial encoding is performed by controlling the magnetic field gradient system to produce a readout gradient during the sampling event which samples k-space in a non-Cartesian order.

9. The magnetic resonance system of claim 2, wherein the calculation of the abundance of each of the predetermined tissue types within each of discrete voxels by comparing the magnetic resonance data for each of the discrete voxels with the magnetic resonance fingerprinting dictionary is performed by:
expressing each magnetic resonance signal of the magnetic resonance data as a linear combination of the signal from each of the set of predetermined substances, and
determining the abundance of each of the set of predetermined substances by solving the linear combination using a minimization technique.

10. The magnetic resonance system of claim 1, wherein one or several dummy sequence modules having a duration equal to the fixed repetition time are applied in the train of pulse repetitions, each dummy sequence being void of RF excitations and sampling events.

11. The magnetic resonance system of claim 10, wherein the train of pulse sequence repetitions is arranged to form a gradient spoiled and optionally pseudo T1-spoiled sequence.

12. The magnetic resonance system of claim 1, wherein execution of the machine executable instructions further causes the processor to calculate the magnetic resonance fingerprinting dictionary.

13. The magnetic resonance system of claim 1, wherein the pulse sequence commands specify the reading out of the k-space center at the fixed delay.

14. A computer program product containing machine executable instructions for execution by a processor controlling a magnetic resonance system for acquiring a magnetic resonance data from a subject within a measurement zone, wherein the magnetic resonance system comprises a magnet for generating a main magnetic field within the measurement zone; wherein the magnetic resonance system further comprises a magnetic field gradient system for generating a gradient magnetic field within the measurement zone in at least one direction by supplying current to a set of magnetic gradient coils for each of the at least one direction, wherein execution of the machine executable instructions causes the processor to:
acquire the magnetic resonance data by controlling the magnetic resonance system with pulse sequence commands, wherein the pulse sequence commands cause the magnetic resonance system to acquire the magnetic resonance data according to a magnetic resonance fingerprinting technique, wherein the pulse sequence commands specify a train of pulse sequence repetitions, wherein each pulse sequence repetition has a fixed repetition time, wherein each pulse sequence repetition comprises either a radio frequency pulse or a sampling event occurring at a fixed delay from the start of the pulse sequence repetition, wherein the radio frequency pulse is chosen from a distribution of radio frequency pulses, wherein the distribution of radio frequency pulses cause magnetic spins to rotate to a distribution of flip angles, wherein the pulse sequence commands specify the application of gradient magnetic fields in the at least one direction by controlling the supplied current to the set of gradient coils, wherein for each of the set of magnetic gradient coils the integral of current supplied is a constant for each fixed repetition time; and
calculate an abundance of each of a set of predetermined substances by comparing the magnetic resonance data with a magnetic resonance fingerprinting dictionary, wherein the magnetic resonance fingerprinting dictionary contains a listing of calculated magnetic resonance signals in response to execution of the pulse sequence commands for a set of predetermined substances.

15. A method of operating a magnetic resonance system to acquire magnetic resonance data from a subject within a measurement zone, wherein the magnetic resonance system comprises a magnet for generating a main magnetic field within the measurement zone, wherein the magnetic resonance system further comprises a magnetic field gradient system for generating a gradient magnetic field within the measurement zone in at least one direction by supplying current to a set of magnetic gradient coils for each of the at least one direction, wherein the method comprises the steps of:
acquiring the magnetic resonance data by controlling the magnetic resonance system with pulse sequence commands, wherein the pulse sequence commands cause the magnetic resonance system to acquire the magnetic resonance data according to a magnetic resonance fingerprinting technique, wherein the pulse sequence commands specify a train of pulse sequence repetitions, wherein each pulse sequence repetition has a fixed repetition time, wherein each pulse sequence repetition comprises either a radio frequency pulse or a sampling event occurring at a fixed delay from the start of the pulse sequence repetition, wherein the radio frequency pulse is chosen from a distribution of radio frequency pulses, wherein the distribution of radio frequency pulses cause magnetic spins to rotate to a distribution of flip angles, wherein the pulse sequence commands specify the application of gradient magnetic fields in the at least one direction by controlling the supplied current to the set of gradient coils, wherein for each of the set of magnetic gradient coils the integral of current supplied is a constant for each fixed repetition time; and
calculating an abundance of each of a set of predetermined substances by comparing the magnetic resonance data with a magnetic resonance fingerprinting dictionary, wherein the magnetic resonance fingerprinting dictionary contains a listing of calculated magnetic resonance signals in response to execution of the pulse sequence commands for a set of predetermined substances.
